(19) United States
(12) Patent Application Publication
(10) Pub. No.: US 2007/0166874 A1
(43) Pub. Date: Jul. 19, 2007

(54) Fabrication Method of Nanoimprint Mold Core

(75) Inventors: Ching-Bin Lin, Hsinchu Hsien (TW); Pao-Yu Cheng, Hsinchu Hsien (TW); Hung-Yi Lin, Hsinchu Hsien (TW)

Correspondence Address: SHOEMAKER AND MATTARE, LTD, 10 POST OFFICE ROAD - SUITE 110, SILVER SPRING, MD, 20910, US

(73) Assignee: INDUSTRIAL TECHNOLOGY RESEARCH INSTITUTE, Hsinchu Hsien (TW)

(21) Appl. No.: 11/626,961

(22) Filed: Jan. 25, 2007

Related U.S. Application Data
(63) Continuation-in-part of application No. 11/034,879, filed on Jan. 14, 2005, now abandoned.

(30) Foreign Application Priority Data
Nov. 24, 2005 (TW) 093136099

(51) Int. Cl. H01L 21/06

(52) U.S. Cl. 438/102

(57) ABSTRACT

A method for fabricating a nanoimprint mold core is disclosed. The method includes providing a substrate; forming on the substrate an amorphous thin film, which is transformed into a crystalline thin film upon receipt of energy, the crystalline thin film having physical and chemical characteristics different from those of the amorphous thin film; applying the energy onto a predetermined region of the amorphous thin film, to transform the amorphous thin film within the predetermined region into the crystalline thin film; etching the illuminated amorphous film, which has crystalline mark on amorphous film, and at least partially removing the area of remained amorphous thin films; performing an imprinting process on the substrate, which has the etched amorphous thin films formed; and performing a molding releasing process on the substrate, so as to obtain the nanoimprint mold core.

This application is a continuation-in-part of U.S. application Ser. No. 11/034879, filed on Jan. 14, 2005.

### FIELD OF THE INVENTION

The present invention relates to fabrication methods of mold cores, and more particularly, to a fabrication method of a nanoimprint mold core.

### BACKGROUND OF THE INVENTION

With the advancement of nanotechnology, a variety of nanostructures can be fabricated by different materials with precision of nanometer or even atomic scale, and different kinds of nano fabrication techniques are accordingly widely researched and developed.

Presently, to fabricate a mold core of a nano scale (below 100 nm), nano-scale fabrication technologies, such as photo lithography, electron-beam (e-beam) direct writing, scattering with angular limitation projection electron beam lithography (SCALPEL), x-ray lithography technology, focused ion beam (FIB) lithography technology and nanoimprint lithography, can be employed to reduce the line width to below 100 nm. The related prior arts include U.S. Pat. Nos. 6,813,077, 6,806,456, 6,803,554, 6,777,172, 6,512,235, and 5,772,905, etc.

In semiconductor fabrication processes, the photo lithography that belongs to an optical lithography technique has been evolved from using a KrF 248 stepper of deep ultraviolet (DUV) lithography to ArF 193 nm and F₂ 157 nm of vacuum ultraviolet (VUV) lithography and then to future 13 nm extreme ultraviolet (EUV) lithography. The e-beam direct writing technology, SCALPEL, x-ray lithography and FIB lithography belong to non-optical lithography techniques. FIGS. 5A to 5D show processes of a conventional fabrication method of a nano mold core using electron-beam lithography (EBL).

First referring to FIG. 5A, a silicon substrate 100 is provided, and a thin film 110 made of such as SiₓN_{y} and SiOₓ is applied on the silicon substrate 100. Then, as shown in FIG. 5B, a photoresist layer 120 is formed on the thin film 110. Subsequently, as shown in FIG. 5C, the photoresist layer 120 is etched by the EBL and post wet etching techniques to define a pattern 130. Finally, as shown in FIG. 5D, the silicon is etched by for example reactive ion etching (RIE) to form a nano mold core 200.

However, the above conventional fabrication method requires an expensive exposure device, which has a low lithography speed but increases the fabrication cost. Further, the conventional fabrication method undesirably has difficulty in fabricating a large area nano mold core, and cannot be used for mass production of chips as an optical stepper does, such that the industrial applicability thereof is restricted.

Moreover, although the EUV lithography and the SCALPEL technology may relatively be more suitable for mass production, the equipment costs thereof are multiplied to about over fifty million U.S. dollars. As a result, these conventional techniques cannot be widely applied in the industries due to the cost considerations.

In addition, Stephen Y. Chou has published nanoimprint lithography (NIL) technology in 1995, which may only utilize one single mold to repeatedly perform imprinting of the same nano pattern and fabrication of a nanostructure on a large area wafer substrate. Consequently, compared to the optical lithography, the NIL technology can achieve the nano-scale or even smaller line width, and compared to the non-optical lithography, the NIL technology has a faster imprint speed. Thus, the NIL technology is considered as an advance technology for realizing mass production of nanostructures.

Therefore, the problem to be solved here is to apply a new fabrication method of a nano mold core complying with the desirable size requirement for NIL technology, so as to resolve the foregoing drawbacks in the conventional optical lithography and non-optical lithography such as high cost, slow speed, difficulty in fabrication, and so on.

### SUMMARY OF THE INVENTION

In light of the above drawbacks in the prior art, a primary objective of the present invention is to provide a fabrication method of a nanoimprint mold core, which has advantages of low cost, high yield and easy fabrication of the mold core.

Another objective of the present invention is to provide a fabrication method of a nanoimprint mold core, so as to fabricate the mold core with a simplified process without traditional photoresist.

Still another objective of the present invention is to provide a fabrication method of a nanoimprint mold core, for improving the industrial applicability of the mold core.

A further objective of the present invention is to provide a fabrication method of a nanoimprint mold core, for improving the design flexibility of the mold core.

In accordance with the above and other objectives, the present invention proposes a method for fabricating a nanoimprint mold core. The method includes providing a substrate; forming on the substrate an amorphous thin film, which is transformed into a crystalline thin film upon receipt of energy, the crystalline thin film having physical and chemical characteristics different from those of the amorphous thin film; applying the energy onto a predetermined region of the amorphous thin film, to transform the amorphous thin film within the predetermined region into the crystalline thin film; etching the crystalline and amorphous thin films; performing an imprinting process on the substrate, which has the etched crystalline and amorphous thin films formed; and performing a molding forming process on the substrate, so as to obtain the nanoimprint mold core. The substrate is preferably a silicon substrate. The amorphous thin film is applied on the substrate by physical vapor deposition such as thermal evaporation, sputtering, or ion planting. The amorphous thin film is a photo phase change alloy target material.

Preferably, the energy is generated by a light source. The light source comprises a low wavelength ray, which is preferably at least one selected from the group consisting of g-line ultraviolet lithography, I-line ultraviolet lithography, KrF laser lithography, ArF laser lithography, F₂ laser lithography, extreme ultraviolet lithography (EUV), femtosecond laser, focused ion beam and e-beam.

An energy controlling member is preferably disposed between the light source and the amorphous thin film of the substrate, and an energy positioning member is disposed between the energy controlling member and the amorphous thin film of the substrate. The energy controlling member may be a light mask or a filter, and the energy positioning member can be an objective lens such as a microscope objective lens.

The amorphous thin film is partially removed by etching. An anti-adhesive layer can be formed on the amorphous thin film before the step of performing the imprinting process using the substrate having the nano pattern, wherein the anti-adhesive layer can be formed by coating or vapor phase deposition. During the step of performing the imprinting process using the substrate having the nano pattern, a polymer layer or a forming layer is applied on the nano pattern by spin coating and subjected to exposure or heating. The polymer layer, and the forming layer as well, is made of a material selected from the group consisting of UV-curable photoresist, thermal-curable resin, and thermal-crosslinking resin. The imprinting process using the substrate having the nano pattern is performed on the same substrate having the nano pattern and the polymer layer or the forming layer. The amorphous thin film is directly formed on the substrate, while the crystalline thin film is indirectly formed on the substrate.

In the present invention, a rapidly heating ray can be employed to perform exposure and development on a photo phase change material, such that the light beam can form a crystalline area or an amorphous area respectively on the amorphous or crystalline photo phase change surface. Then, a positive or negative nano mold core is formed on the photo phase change surface by an etching technique and is for use with nanoimprinting.

Therefore, by the fabrication method of the nanoimprint mold core in the present invention, advantages of low cost, high yield and easy fabrication of the mold core can be achieved, and also the mold core with a more precise line width due to simplified process can be fabricated. This solves the problems in the prior art such as high cost, difficult fabrication and failure in mass production, and improves the industrial applicability and design flexibility of the nanoimprint mold core fabricated in the present invention.

### BRIEF DESCRIPTION OF THE DRAWINGS

The present invention can be more fully understood by reading the following detailed description of the preferred embodiment, with reference made to the accompanying drawing wherein:

FIGS. 1A to 1F are schematic diagrams showing a fabrication method of a nanoimprint mold core in accordance with a first preferred embodiment of the present invention;

FIGS. 2A to 2C are schematic diagrams showing alternative examples of the fabrication method in accordance with the first preferred embodiment, wherein FIGS. 2A and 2B are alternative examples of a light source, and FIG. 2C shows a lithography driving system applied in the first preferred embodiment;

FIGS. 3A to 3D are schematic diagrams showing a fabrication method of a nanoimprint mold core in accordance with a second preferred embodiment of the present invention;

FIGS. 4A to 4C are schematic diagrams showing a fabrication method of a nanoimprint mold core in accordance with a third preferred embodiment of the present invention; and

FIGS. 5A to 5D (PRIOR ART) are schematic diagrams showing a conventional fabrication method of a nano mold core.

### DETAILED DESCRIPTION OF THE PREFERRED EMBODIMENTS

A fabrication method of a nanoimprint mold core proposed in the present invention employs phase change materials so as to directly fabricate a positive or negative mold core with low cost and by rapid lithography that is for use with large area nanoimprinting. The structure of the mold core and the operation principles thereof vary in response to nanoimprint products such as optical passive elements, organic electronic and optical electronic elements, electronic elements, magnetic elements, molecular elements, single electron channel elements, quantum dot elements, prerecording media, biomedical chips, and so on, which are all conventional. Thus, it is to be noted that the associated drawings showing the structure and shape of the mold core in the following embodiments are only for illustration but not for limiting the present invention.

### First Preferred Embodiment

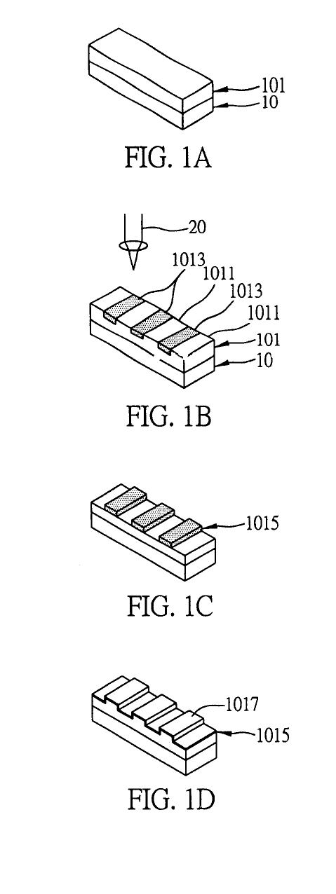

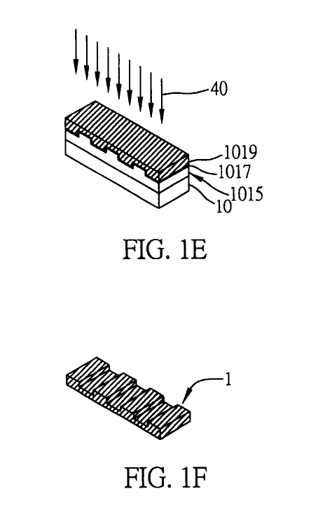

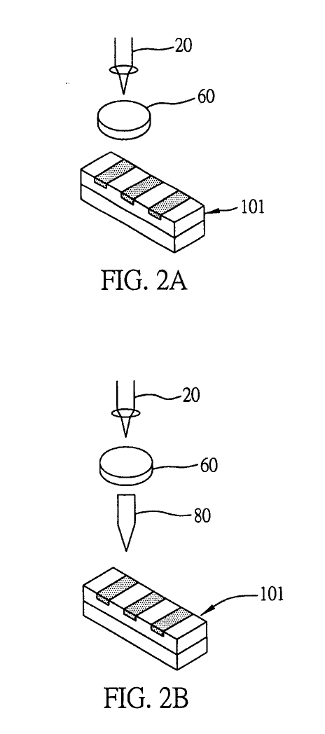

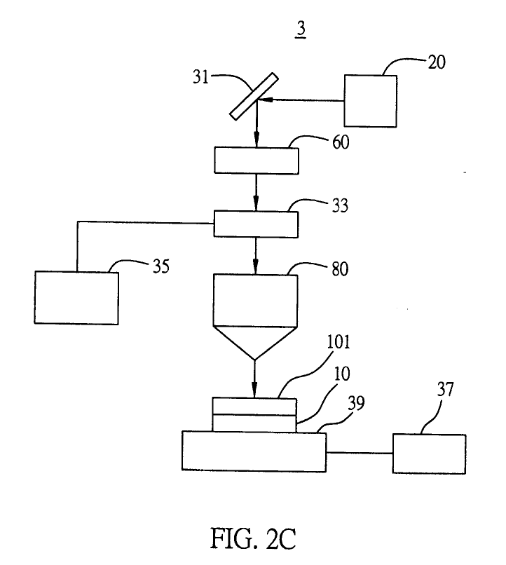

FIGS. 1A to 2C show a fabrication method of a nanoimprint mold core in accordance with a first preferred embodiment of the present invention.

Firstly, a substrate having a photo phase change surface is provided. As shown in FIG. 1A, a substrate 10 is prepared, which can be a flat silicon substrate. A thin film 101 is formed on the substrate 10 by a physical vapor deposition technique such as thermal evaporation, sputtering or ion planting, or by other appropriate processing techniques. The thin film 101 is made of a photo phase change alloy target material such as Ge—Sb—Te (GST), Ge—Te—Sb—S, Te—TeO₂—Ge—Sn, Te—Ge—Sn—Au, Ge—Te—Sn, Sn—Se—Te, Sb—Se—Te, Sb—Se, Ga—Se—Te, Ga—Se—Te—Ge, In—Se, In—Se—Tl—Co, Ge—Sb—Te, GeSbTe+CrTe, GeSbTeCo, Ge—Sb—Te—Tl—Ag, In—Se—Te, Ag—In—Sb—Te, Te—TeO₂, Te—TeO₂—Pd, Sb₂Se₃/Bi₂Te₃, Ag—Zn, Au₃Sn₇, AuSb, In—Sb, Cu—Al—Ni, In—Sb—Se or In—Sb—Te, or other photo phase change materials. The thin film 101 forms a photo phase change surface of the substrate 10. The thin film 101 is an amorphous thin film, which is transformed into a crystalline thin film upon receipt of energy, the crystalline thin film having physical and chemical characteristics different from those of the amorphous thin film.

Then, a predetermined region of the photo phase change surface is subjected to a phase change to form at least one first area and at least one second area. As shown in FIG. 1B, a light source 20 is employed to illuminate the thin film 101 serving as the photo phase change surface of the substrate 10. The light source 20 illuminates the thin film 101 to generate photomelting and thus rapidly have a phase change, such that at least one first area (amorphous thin film) 1011 outside of the predetermined region and a plurality of second areas (crystalline thin film) 1013 within the predetermined region are formed. The light source 20 is for example g-line ultraviolet rays, I-line ultraviolet rays, KrF laser , ArF laser, F₂ laser, extreme ultraviolet (EUV) rays, femtosecond laser, focused ion beam, e-beam or other equivalent low wavelength rays. In this embodiment, the Ge₂—Sb₂—Te₅ thin film can be illuminated by for example, but not limited to, femtosecond laser pulse.

Subsequently, the first area 1011 is at least partially removed to form a nano pattern. As shown in FIG. 1C, by the different physical and chemical properties of the first area 1011 and the second areas 1013, the first area 1011 can be partially removed by etching or other appropriate techniques so as to form a nano pattern 1015. In this embodiment, for example, as high-temperature enthalpy atoms in the first area 1011 (amorphous region) are easier to be etched than atoms in the second areas 1013 (crystalline marks), part of the first area 1011 can be removed to form the desirable nano pattern 1015.

Next, as shown in FIG. 1D, an anti-adhesive layer 1017 is applied on the nano pattern 1015 by coating or vapor phase deposition. The anti-adhesive layer 1015 can be made of tridecafluoro-(1,1,2,2)-tetrahydroctyl-trichlorosilane (F₁₃-TCS), C₈H₄CI₁₃Si, or other appropriate materials. It should be noted that, in this embodiment, the anti-adhesive layer 1017 is formed on the nano pattern 1015, for preventing the mold core from attaching to undesirable polymers during an imprinting process, however, in other embodiments, the anti-adhesive layer is not necessary.

After that, the substrate having the nano pattern is used to perform an imprinting process. As shown in FIG. 1E, a polymer layer 1019 is optionally applied on the nano pattern 1015 having the anti-adhesive layer 1017 by spin coating, and is then subjected to exposure. In this embodiment, the polymer layer 1019 can be made of UV-curable photoresist, and ultraviolet ray 40 is used to perform exposure. In other embodiments, thermal-crosslinking resin or other equivalent photoresist materials and light sources can also be adopted to perform imprinting on the substrate 10. Moreover, the substrate 10 having the polymer layer 1019 can be optionally placed into an oven (not shown) to perform pre-baking at 80° C. for 30 minutes, and a pressure of smaller than 0.1 N/mm² is applied on the polymer layer 1019 to perform UV curing.

Finally, a mold releasing process is carried out so as to obtain a mold core. As shown in FIG. 1F, the mold core 1 having nanostructures is obtained after performing the mold releasing process. Since the mold releasing process employs conventional technology, it is not to be further detailed herein.

The obtained mold core 1 can be applied to nanostructures, such as nano dots, nano holes, nano islands, nano lines, nano channels, nano chambers, nano gecko sole cupule shaped hairs, and so on; optical passive elements, such as gratings, resonators, subwavelength optical elements, polarizers, light filters, Fresnel zone plates, photonic crystals, and so on; organic electronic and optical electronic elements, such as organic transistors, organic semiconductors, organic light emitting diodes, organic lasers, and so on; electronic elements and magnetic elements, such as transistors, field effect transistors, pseudomorphic high electron mobility transistors (pHEMTs), optical detectors, and so on; magnetic elements and microstructures, such as magnetic prerecording discs, magnetic valves, and so on; molecule elements, single electron channel elements and quantum dot elements, such as molecule switches, nano contact dots of molecule elements, single electron channels, wave guide elements, quantum-well and quantum dot elements, and so on; prerecording media, such as optical prerecording discs and magnetic prerecording discs; and biomedical chips, such as cobalt nano dots, nano liquid channels, molecule film chips having nano holes, DNA electrophoresis chips, and so on.

In this embodiment, the light source 20 shown in FIG. 1B can be employed to illuminate the thin film 101, wherein the light source 20 can be femtosecond laser pulse. Thus, for photomelting, the thin film 101 made of GST can be selected as an active material, and the GST amorphous thin film has fast and stable phase changing features. Consequently, when using the femtosecond laser pulse to illuminate the GST thin film, the illumination time is about 10⁻¹⁵ second and is considerably short compared to the conventional laser pulse (10⁻⁹).

Further, as shown in FIG. 2A, an energy controlling member 60 can be disposed in the predetermined path of the light source 20 for illuminating the thin film 101, such that the energy controlling member 60 can control the energy of the light source 20 illuminated on the thin film 101. Moreover, as shown in FIG. 2B, an energy positioning member 80 can be further disposed between the energy controlling member 60 and the thin film 101, such that the energy positioning member 80 can precisely control the position of the thin film 101 being illuminated by the light source 20. The energy controlling member 60 can be an optical mask, a filter, or other equivalent elements. The energy positioning member 80 can be a microscope objective lens or other equivalent elements. Thus, the fabricated nano pattern can be more precisely controlled and have nanostructures with a smaller line width.

As shown in FIG. 2C, a lithography driving system 3 can be further provided to perform regulation and feedback on the phase change. For example, a reflector 31 can be disposed in the illumination direction of a laser light source (such as the light source 20). The energy controlling member 60 controls the reflected light source 20 from the reflector 31. An electrical shutter 33 can be disposed between the energy controlling member 60 and the energy positioning member 80, and is controlled by a computer 35. The substrate 10 can be mounted on a platform 39 that is controlled by an actuator 37. Accordingly, the lithography driving system 3 is effective to control the illumination time, energy, position and other relevant factors during the phase change. In this embodiment, the substrate 10 can be optionally moved, and the light source 20 is fixed in position, so as to align the position of the thin film 101 intended to be illuminated with the light source 20. Alternatively, in other embodiments, the light source 20 can also be moved to control the illumination energy and position of the thin film 101. Furthermore, the heat affected zone of illumination can be controlled to a picosecond scale, such that the nano pattern can be precisely formed on the laser dot area. In other words, no matter in the case of fixing the illumination direction of the light source and driving the substrate having the photo phase change material by the actuator to scan back and forth, or in the case of driving the light source to scan back and forth the substrate having the photo phase change material and fixed in position, the desirable nano pattern can both be formed.

In addition, during illumination using the femtosecond laser pulse, as shown in FIG. 1B, the laser beam, i.e. the light source 20, can be controlled by lithography software and a precision driving system. The amorphous region, i.e. the first area 101 in this embodiment, can be partially melted by laser pulse; and the crystalline marks, i.e. the illuminated areas 1013 in this embodiment, can be shaped during a rapid cooling process due to the relative high volume of substrate and high thermal conductivity itself, wherein the cooling speed thereof is faster than the threshold cooling speed. Then, after illumination, the laser vertex is lifted and moved to the next position where the nano pattern is to be formed. The above operation is continued until all of the desirable pattern areas are illuminated.

Compared to the conventional technology having the drawbacks of high cost, slow speed and difficult fabrication, the present invention merely employs a rapid heating light source to perform exposure and development on the photo phase change material surface, and allow the photo phase change material to be subjected to a phase change by the exposure energy of rays so as to form crystalline areas in amorphous film. Since the physical and chemical properties of the crystalline areas and the amorphous areas are different from each other, secondary processing or shaping is carried out to fabricate a nanoimprint mold core. The present invention not only has advantages of low cost, high yield, and easy fabrication of the mold core, thereby solving the drawbacks of the conventional technology, but also can fabricate a mold core having a smaller line width, such that the product quality and industrial applicability are improved. Since the present invention adopts the photo phase change material, i.e. GST amorphous thin film, which comprises metal and is rigid enough to be the mold core 200 after being processed by the phase change process, further processes, such as the metal lift-off process that the conventional technology has to use because the conventional technology adopt the soft photoresist layer 120, is thereby omitted.

### Second Preferred Embodiment

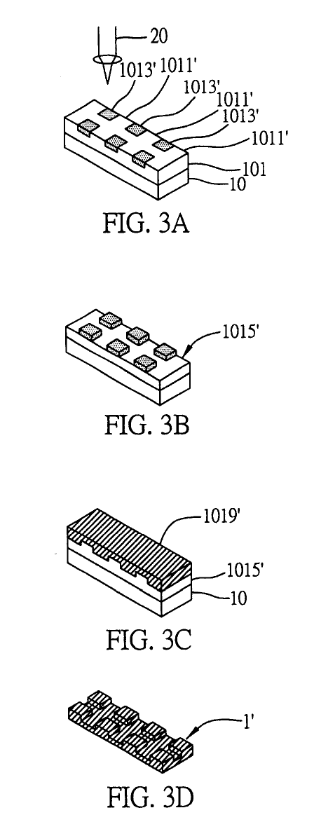

FIGS. 3A to 3D show a fabrication method of a nanoimprint mold core in accordance with a second preferred embodiment of the present invention. In the second embodiment, same or similar elements as or to those in the first embodiment are designated with the same or similar reference numerals, and detailed descriptions thereof are omitted for the sake of simplification and clarity.

The second embodiment primarily differs from the first embodiment in that a large area nano pattern is formed in the first embodiment, whereas a matrix nano pattern is fabricated in the second embodiment.

As shown in FIG. 3A, the light source 20 is employed to illuminate the thin film 101 serving as the photo phase change surface of the substrate 10, so as to form at least one first area (amorphous thin film) 1011′ and a plurality of matrix second areas (crystalline thin film) 1013′. Then, as shown in FIG. 3B, the first area 1011′ is at least partially removed to form a nano pattern 1015′. The foregoing process of forming an anti-adhesive layer as shown in FIG. 1D can be omitted. Subsequently, as shown in FIG. 3C, a polymer layer 1019′ is formed, and the substrate 10 having the nano pattern 1015′ is subjected to an imprinting process. Finally, as shown in FIG. 3D, a mold core 1 is obtained after a mold releasing process is complete.

### Third Preferred Embodiment

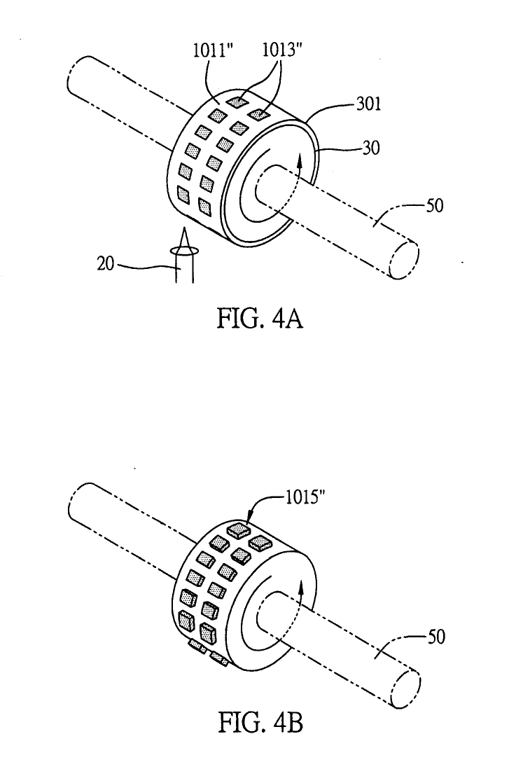

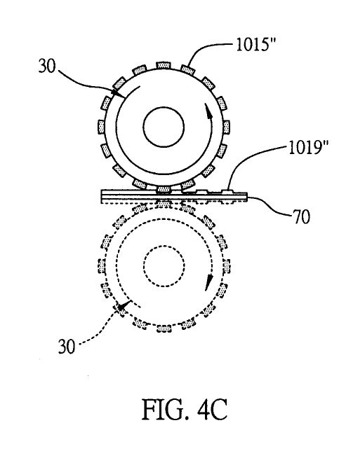

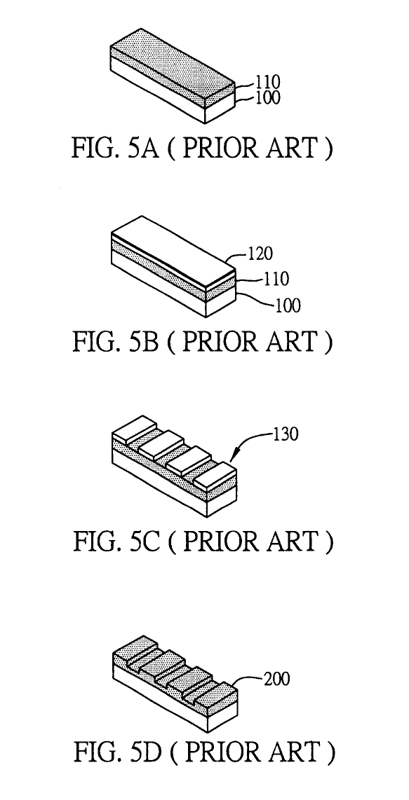

FIGS. 4A to 4C show a fabrication method of a nanoimprint mold core in accordance with a third preferred embodiment of the present invention. In the third embodiment, same or similar elements as or to those in the above embodiments are designated with the same or similar reference numerals, and detailed descriptions thereof are omitted for the sake of simplification and clarity.

As shown in FIG. 4A, the flat substrate 20 in the foregoing embodiments is replaced by a wheel shaped substrate 30. In this embodiment, the substrate 30 can be rotatably supported by a shaft 50, and a photo phase change surface 301 is formed on a radial circumferential surface of the substrate 30. The light source 20 illuminates the photo phase change surface 301 from an underneath position so as to form at least one first area (amorphous thin film) 1011″ and a plurality of matrix second areas (crystalline thin film) 1013″.

Then, a nano pattern 1015″ is formed as shown in FIG. 4B. Finally, as shown in FIG. 4C, a forming layer 1019″ made of UV-curable resin or thermal-curable resin on a flat substrate 70 is cured and continuously shaped by means of the wheel shaped substrate 30. The substrate 70 having the forming layer 1019″ can be optionally placed into an oven (not shown) to perform pre-baking at 80° C. for 30 minutes, and a pressure of 8 N/mm² is applied on the forming layer 1019″ to cure the forming layer 1019″. Thus, a mold releasing process is performed on the substrate 70 so as to obtain a polymeric mold core or device having nanostructures.

Consequently, the fabrication method of the nanoimprint mold core in this embodiment can imprint a substrate with a nano pattern to another substrate having a forming layer, and then perform a mold releasing process on the substrate having forming layer to obtain a mold core with nanostructures. This embodiment is thus different from the foregoing embodiments in which the same substrate is formed with a nano pattern and a forming layer is then subjected to imprinting and mold releasing processes. Furthermore, as shown in FIG. 4C, two substrates both formed with nano patterns can be simultaneously imprinted to a substrate having photo phase change surfaces on both sides thereof.

Moreover, although the flat or wheel shaped substrate is used in the above embodiments for fabricating the nanoimprint mold core, it should be understood for a person skilled in the art to utilize other substrates with a curved surface or other irregular shapes in the present invention, and the substrate can be a flexible or non-flexible substrate, which equivalent modification is obvious to the person skilled in the art.

From the above description, the fabrication method of the nanoimprint mold core in the present invention provides flexibility in design and practice, and simple modifications or replacements can be applied to the above embodiments. For example, the anti-adhesive layer 1017 in the first embodiment can also be formed in any one of the second and third embodiments; the shapes, numbers and disposed positions of the first and second areas in the first and second embodiments can be exchanged or modified according to practical requirements; and the lithography driving system 3 in the first embodiment can also be employed in the second and third embodiments, wherein the depth of phase change may reach the substrate or not reach the substrate. All of the above modifications or replacements are included in the present invention.

Therefore, the fabrication method of the nanoimprint mold core in the present invention has advantages of low cost, high yield, and easy fabrication of the mold core, and can fabricate the mold core having a smaller line width, without causing any difficulty in fabrication. This improves the industrial applicability and design flexibility of the present invention, and also overcomes the drawbacks in the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a nanoimprint mold core, the method comprising:
providing a substrate;
forming on the substrate an amorphous thin film, which is transformed into a crystalline thin film upon receipt of energy, the crystalline thin film having physical and chemical characteristics different from those of the amorphous thin film;
applying the energy onto a predetermined region of the amorphous thin film, to transform the amorphous thin film within the predetermined region into the crystalline thin film;
etching the crystalline and amorphous thin films;
performing an imprinting process on the substrate, which has the etched crystalline and amorphous thin films formed; and
performing a molding releasing process on the substrate, so as to obtain the nanoimprint mold core.

2. The method of claim 1, wherein the amorphous thin film is a photo phase change alloy target material.

3. The method of claim 2, wherein the photo phase change alloy target material is Ge₂—Sb₂—Te₅(GST).

4. The method of claim 3, wherein the Ge₂—Sb₂—Te₅(GST) is formed on the substrate by a physical vapor deposition technique.

5. The method of claim 4, wherein the physical vapor deposition technique is selected from the group consisting of thermal evaporation, ion planting, and sputtering techniques.

6. The method of claim 3 further comprising providing femtosecond laser pulses to generate the energy.

7. The method of claim 6, wherein the femtosecond laser pulses is illuminated on the amorphous thin film within the predetermined region for duration of 10-15 second level.

8. The method of claim 3 further comprising providing a light source to generate the energy.

9. The method of claim 8, wherein the light source is selected from the group consisting of g-line ultraviolet rays, I-line ultraviolet rays, KrF laser, ArF laser, F₂ laser, and extreme ultraviolet rays.

10. The method of claim 8 further comprising providing an energy controlling member disposed between the light source and the crystalline thin film.

11. The method of claim 10, wherein the energy controlling member is either of a light mask and a filter.

12. The method of claim 10 further comprising providing an energy positioning member disposed between the energy controlling member and the amorphous thin film.

13. The method of claim 12, wherein the energy positioning member is an objective lens.

14. The method of claim 12 further comprising providing an electrical shutter disposed between the energy controlling member and the energy positioning member.

15. The method of claim 14, wherein the electrical shutter is controlled by a computer.

16. The method of claim 1, wherein the amorphous thin film is formed directly on the substrate, while the crystalline thin film is formed indirectly on the substrate.

17. The fabrication method of claim 1 further comprising forming an anti-adhesive layer on the etched crystalline and amorphous thin film before the imprinting process is performed on the substrate.

18. The fabrication method of claim 17, wherein the anti-adhesive layer is formed by either of coating and vapor phase deposition techniques.

19. The fabrication method of claim 1 further comprising forming either on of a polymer layer and a forming layer on the etched crystalline and amorphous thin film before the imprinting process is performed on the substrate.

20. The fabrication method of claim 19, wherein both the polymer layer and the forming layer are made of a material selected from the group consisting of UV-curable photoresist, thermal-curable resin, and thermal-crosslinking resin.

21. The fabrication method of claim 1, wherein substrate is wheel-shaped.

22. The fabrication method of claim 1, wherein the crystalline thin film is disposed in a matrix.
